(19) United States
(12) Patent Application Publication
(10) Pub. No.: US 2011/0159677 A1
(43) Pub. Date: Jun. 30, 2011

(54) METHOD OF FABRICATING LANDING PLUG CONTACT IN SEMICONDUCTOR MEMORY DEVICE

(75) Inventor: Jin Yul LEE, Icheon-si (KR)

(73) Assignee: Hynix Semiconductor Inc., Icheon-si (KR)

(21) Appl. No.: 12/976,528

(22) Filed: Dec. 22, 2010

(30) Foreign Application Priority Data
Dec. 30, 2009 (KR) 10-2009-0134672

(51) Int. Cl. H01L 21/28

(52) U.S. Cl. 438/586; 257/E21.158

(57) ABSTRACT

A landing plug contact in a semiconductor memory device is fabricated by: forming gate spacer layers at sides of the gate stacks to define a first contact hole and a second contact hole, where a landing plug contact will be formed between the gate spacer layers of the first contact hole and no landing plug contact is formed in the second contact hole; forming a conductive layer to fill at least the first and second contact holes; forming a hard mask pattern over the conductive layer to expose the conductive layer filling the second contact hole; removing the conductive layer filling the second contact hole by an etching process; forming an insulation layer to fill at least the second contact hole where the conductive layer is removed; and forming a landing plug contact within the contact hole by performing a planarization process on the insulation layer and the conductive layer.

### CROSS-REFERENCES TO RELATED APPLICATIONS

The present application claims priority under 35 U.S.C 119(a) to Korean application number 10-2009-134672, filed on Dec. 30, 2009, in the Korean intellectual property Office, which is incorporated herein by reference in its entirety.

### BACKGROUND

Exemplary embodiments of the present invention relate generally to a method of fabricating a semiconductor device, and more particularly to a method of fabricating a landing plug contact (LPC) in a semiconductor memory device.

Landing plug contacts are used in high density dynamic random access memories (DRAM) implemented with transistors and capacitors to electrically connect a doped region of a semiconductor substrate to a bit line and to a storage node. A landing plug contact is formed by using a conductive layer to fill a gap contacting a doped region of a semiconductor substrate in a space between word lines composed of a gate stack. A bit line contact and a storage contact are formed to be coupled to the landing plug contact.

In order to form the landing plug contact, a gate spacer layer, which insulates a gap between the gate stack and the landing plug contact, is formed at a side of the gate stack over the semiconductor substrate. An insulation layer is deposited over the resulting structure and a planarization process is performed thereon. Subsequently, a self aligned contact (SAC) etching process is performed to form a landing plug contact hole exposing a predetermined portion of the semiconductor substrate between the gate stacks, at which a landing plug contact will be formed. A conductive layer for a landing plug contact, for example, a polycrystalline silicon layer, is deposited to fill the landing plug contact hole and then planarized to form a landing plug contact.

However, due to excess etching during the SAC etching process for forming the landing plug contact hole, the gate spacer layer may be etched together, and a hard mask nitride layer disposed over the gate stack to protect an underlying gate conductive layer may be excessively lost. Additionally, in the case of a recessed gate structure, a device isolation layer surrounding a recessed gate may be lost. In this case, the landing plug contact and the gate stack are bridged and thus they are not electrically isolated from each other, causing malfunction of the semiconductor memory device. Furthermore, when the pitch of the semiconductor memory device is reduced to below 50 nm, a portion of the insulation layer is not etched during the SAC etching process for forming the landing plug contact hole. Consequently, a serious problem, called a landing plug not-open phenomenon, is incurred so that the landing plug contact hole is not formed.

### SUMMARY

An embodiment of the present invention relates to fabricating a landing plug contact in a semiconductor memory device, which is capable of substantially reducing a landing plug not-open phenomenon and a bridge phenomenon, thereby suppressing malfunction of the semiconductor memory device.

In an embodiment, a landing plug contact in a semiconductor memory device is fabricated by: forming a device isolation layer defining an active region in a substrate; forming a gate stack over the substrate; forming gate spacer layers at sides of the gate stack to define a first contact hole in which a landing plug contact will be formed between the gate spacer layers, and a second contact hole in which no landing plug contacts are formed; forming a conductive layer over a resulting structure to fill the first contact and the second contact hole; forming a hard mask pattern over the conductive layer to expose the conductive layer filling the second contact hole; removing the conductive layer filling the second contact hole by an etching process using the hard mask pattern as an etching barrier; forming an insulation layer over a resulting structure to fill the second contact hole in which the conductive layer is removed; and forming a landing plug contact, which is mutually insulated from an adjacent landing plug contact, within the contact hole by performing a planarization process on the insulation layer and the conductive layer.

The hard mask pattern may include an amorphous carbon layer.

The etching process using the hard mask pattern as the etching barrier may be performed using an etching gas having a high etch selectivity between the conductive layer, the gate spacer layer, and the device isolation layer. In this case, the conductive layer, the gate spacer layer, and the device isolation layer may include a polycrystalline silicon layer, a nitride layer, and an oxide layer, respectively, and Cl gas and HBr gas may be used as the etching gas.

The insulation layer may include a boron phosphorous silicate glass (BPSG) oxide layer. In this case, before forming the BPSG oxide layer, the method may further include forming a buffer layer which suppresses penetration of impurities. The buffer layer may include a nitride layer.

Further, in an embodiment of the present invention, a landing plug contact in a semiconductor memory device is fabricated by: forming a device isolation layer defining an active region in a substrate having a cell region and a peripheral region; forming a gate stack over the substrate; forming gate spacer layers at sides of the gate stack to define a first contact hole in which a landing plug contact will be formed between the gate spacer layers, and a second contact hole in which no landing plug contacts are formed; forming a conductive layer over a resulting structure to fill the first contact and the second contact hole; forming a hard mask pattern over the conductive layer to expose the conductive layer filling the second contact hole and the conducive layer within the peripheral region; removing the conductive layer filling the second contact hole within the cell region and the conductive layer within the peripheral region by an etching process using the hard mask pattern as an etching barrier; forming an insulation layer over a resulting structure to fill the second contact hole in which the conductive layer is removed; and forming a landing plug contact, which is insulated from an adjacent landing plug contact, within the contact hole by performing a planarization process on the insulation layer and the conductive layer.

The hard mask pattern may include an amorphous carbon layer.

The etching process using the hard mask pattern as the etching barrier may be performed using an etching gas having a high etch selectivity between the conductive layer, the gate spacer layer, and the device isolation layer. In this case, the conductive layer, the gate spacer layer, and the device isolation layer may include a polycrystalline silicon layer, a nitride layer, and an oxide layer, respectively, and CI gas and HBr gas may be used as the etching gas.

### BRIEF DESCRIPTION OF THE DRAWINGS

The above and other features and advantages will be more clearly understood from the following detailed description taken in conjunction with the accompanying drawings, in which:

FIGS. 1 to 15 are views for illustrating a method of fabricating a landing plug contact in a semiconductor memory device according to an embodiment of the present invention.

### DESCRIPTION OF SPECIFIC EMBODIMENTS

Hereinafter, embodiments of the present invention will be described with reference to the accompanying drawings. The drawings are not necessarily to scale and in some instances, proportions may have been exaggerated in order to clearly depict certain features of the invention.

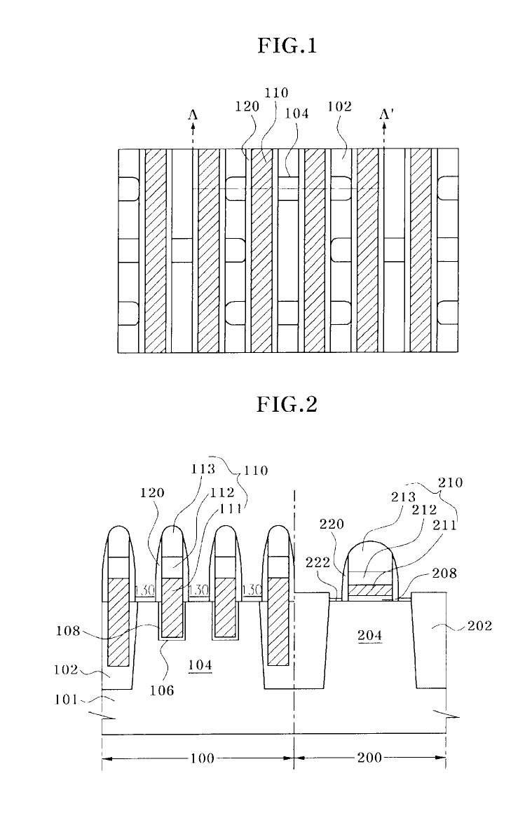

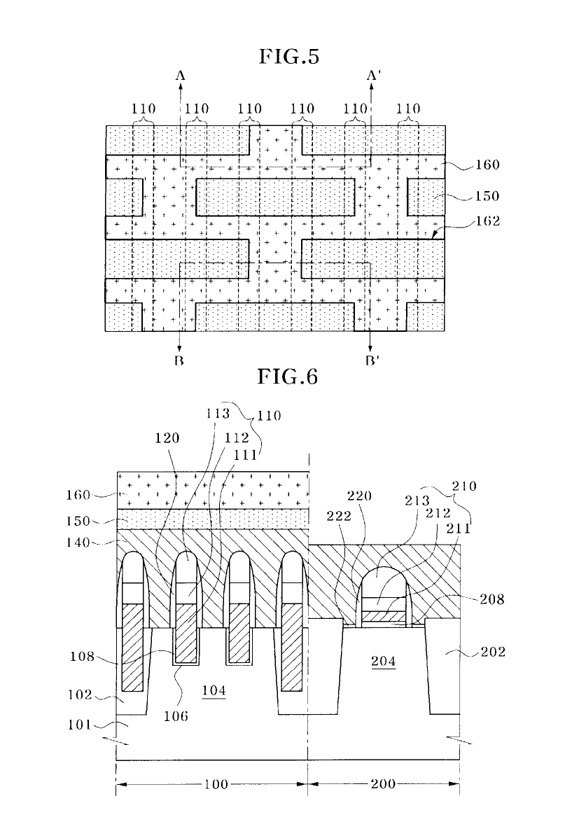

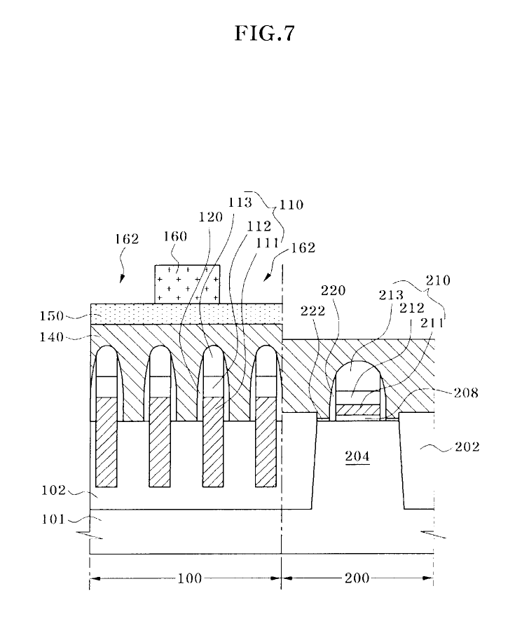

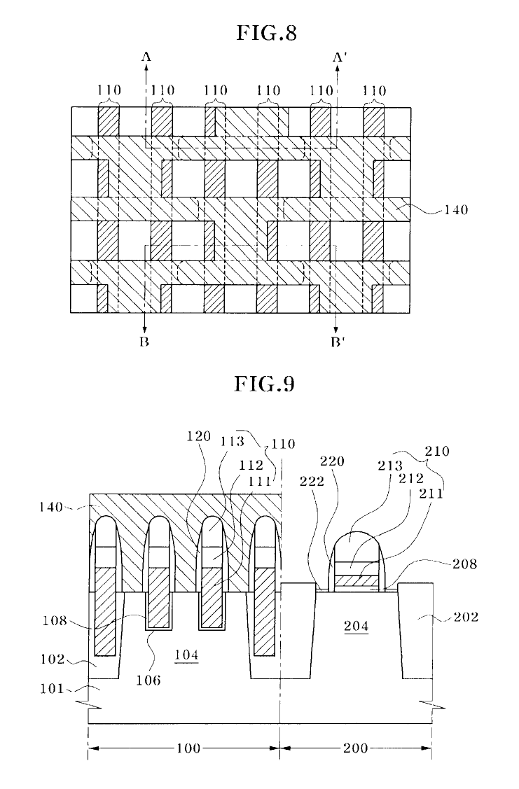

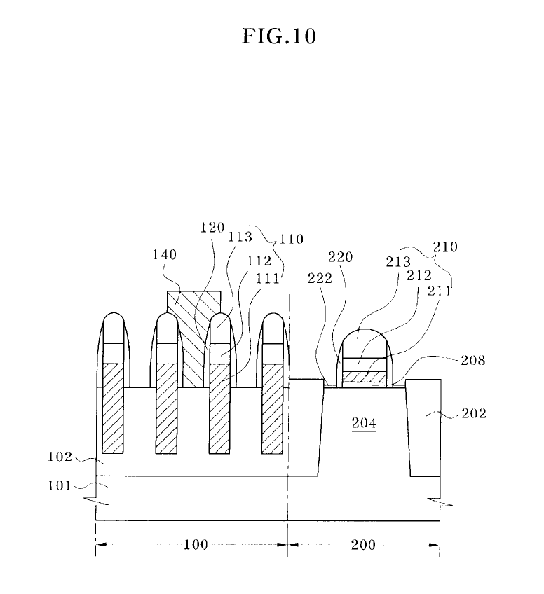

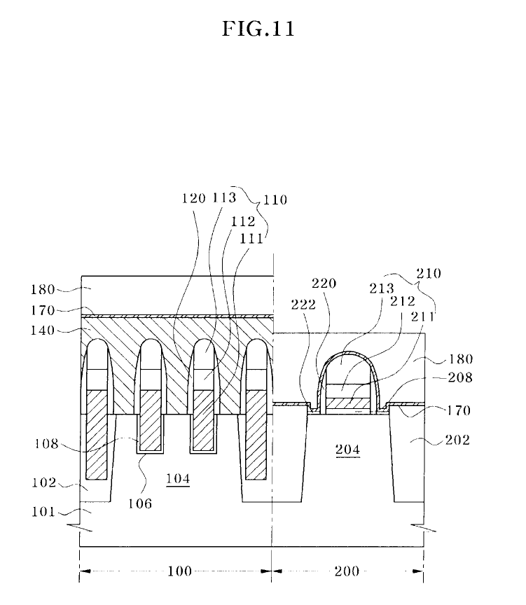

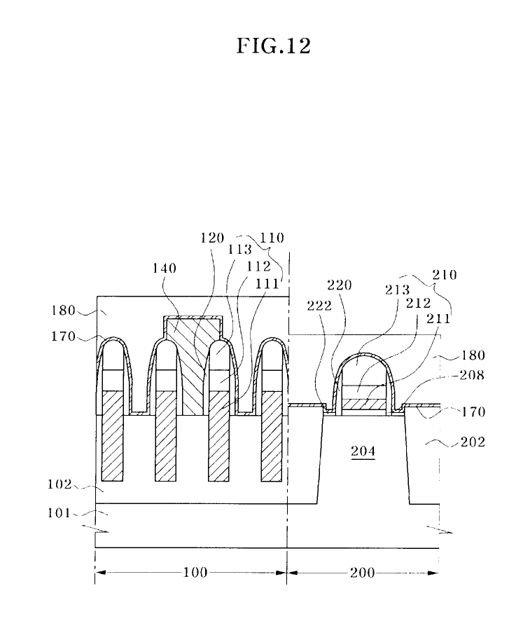

FIGS. 1 to 15 are views for illustrating a method of fabricating a landing plug contact in a semiconductor memory device according to an embodiment of the present invention. Specifically, FIGS. 2, 4, 6, 9, and 14 are cross-sectional views taken along lines A-A′ of FIGS. 1, 3, 5, 8, and 13, respectively. FIGS. 7, 10, and 15 are cross-sectional views taken along lines B-B′ of FIGS. 5, 8, and 13, respectively. Although plan views are not illustrated, FIGS. 11 and 12 are cross-sectional views taken along lines A-A′ and B-B′ of FIG. 8 after a subsequent process is performed, respectively. For simplicity and understanding of the drawings, gate spacer layers are not illustrated in some plan views and active regions are indicated by dotted lines.

Referring to FIGS. 1 and 2, active regions 104 and 204 are defined by device isolation layers 102 and 202 formed in a substrate having a cell region 100 and a peripheral region 200. A well region and a channel region may be formed by an ion implantation process, and a trench 106 for a recessed gate is formed in the cell region 100. Gate dielectric layers 108 and 208 are formed in the trench 106 of the cell region 100 and the active region 204 of the peripheral region 200, respectively. For example, the gate dielectric layers 108 and 208 may be formed with oxide layers having a thickness of approximately 30 Å to approximately 60 Å. In the cell region 100, a gate conductive layer, a gate metal layer, and a gate hard mask layer are sequentially stacked over the gate dielectric layer 108, so that the inside of the trench 106 is filled. In the peripheral region 200, a gate conductive layer, a gate metal layer, and a gate hard mask layer are sequentially stacked over the gate dielectric layer 208. A recessed gate stack 110 comprising a gate conductive pattern 111, a gate metal pattern 112, and a gate hard mask pattern 113 that are stacked is formed in the cell region 100 by a gate patterning process. A planar gate stack 210 comprising a gate conducive pattern 211, a gate metal pattern 212, and a gate hard mask pattern 213 that are stacked is formed in the peripheral region 200. The gate conductive layer may include, for example, a polycrystalline silicon layer having a thickness of approximately 400 Å to approximately 1,500 Å. The gate metal layer may include, for example, a tungsten (W) layer having a thickness of approximately 400 Å to approximately 600 Å. The gate hard mask layer, for example, may include a nitride layer having a thickness of approximately 2,000 Å to approximately 2,500 Å.

Gate spacer layers 120 are formed at sides of the recessed gate stack 110 of the cell region 100, and gate spacer layers 220 are formed at sides of the planar gate stack 210 of the peripheral region 200. Then, a nitride layer having a thickness of approximately 60 Å to approximately 80 Å and an oxide layer 222 having a thickness of approximately 100 Å to approximately 120 Å are formed over the resulting structure. The oxide layer 222 in the cell region 100 is removed using a mask pattern, which covers the peripheral region 200 but exposes the cell region 100. As a result, the oxide layer 222 remains only on the surface of the peripheral region 200 of the substrate 101. Then, an insulation layer is formed over the resulting structure for formation of gate spacer layers. The insulation layer may include, for example, a nitride layer having a thickness of approximately 90 Å to approximately 110 Å. Subsequently, gate spacer layers 120 and 220 are formed by performing a typical anisotropic etching process on the insulation layer. By forming the gate spacer layers 120 and 220, a gap between two gate spacer layers 120, that is, a contact hole 130, is defined in the cell region 100. The contact hole 130 may be a first contact hole in which a landing plug contact is formed or a second contact hole in which no landing plug contact is formed. After forming the gate spacer layers 120 and 220, a cleaning process is performed.

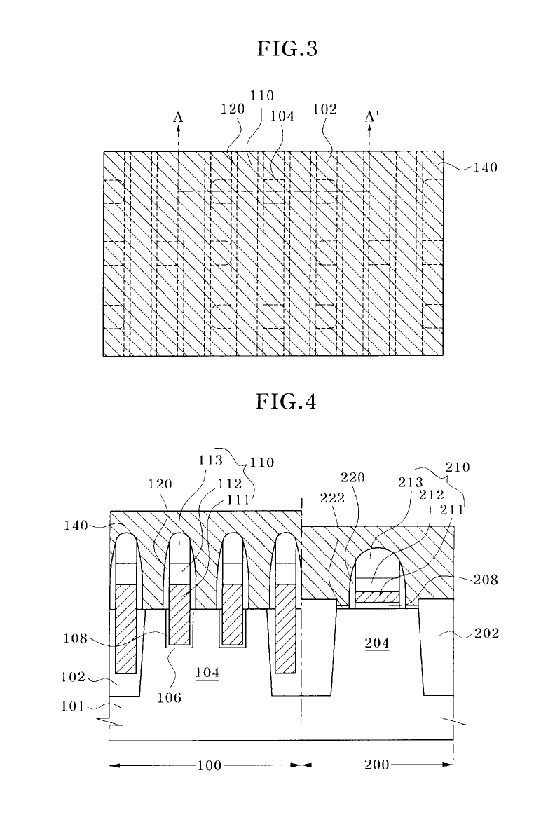

Referring to FIGS. 3 and 4, a conductive layer 140 is deposited over the resulting structure for formation of a landing plug contact. The conductive layer 140 may include a polycrystalline silicon layer having a thickness of approximately 500 Å to approximately 800 Å. The polycrystalline silicon layer may be formed in a chemical vapor deposition (CVD) process. Specifically, the substrate 101 is loaded in a CVD chamber at a temperature of approximately 300° C. Silane (SiH₄) gas is then supplied into the CVD chamber so that a polycrystalline silicon layer can be formed of solid phase epitaxy (SPE) on the substrate 101. The contact hole 130 in the cell region 100 would be completely filled with the conductive layer 140 having been deposited, and it is thereby possible to reduce or prevent the landing plug not-open phenomenon in the form of the contact hole 130 not being filled with the conductive layer.

Referring to FIGS. 5 to 7, a hard mask layer 150 is deposited over the conductive layer 140 in the cell region 100. The hard mask layer 150 may include, for example, an amorphous carbon layer. A mask pattern 160 is formed over the hard mask layer 150. The mask pattern 160 may include, for example, a photoresist layer. The mask pattern 160 has an opening 162 exposing the hard mask layer 150 provided over the conductive layer 140 which must be removed for mutual insulation. In order to ensure a sufficient margin, the opening 162 of the hard mask layer 150 may be aligned up to the center portion of the recessed gate stack 110.

Referring to FIGS. 8 to 10, an exposed portion of the hard mask layer 150 is removed using the mask pattern 160 as an etching mask, thereby forming a hard mask pattern exposing a portion of the underlying conductive layer 140. After forming the hard mask pattern, the mask pattern 160 is removed. An exposed portion of the conductive layer 140 is removed by an etching process using the hard mask pattern as an etching barrier. The etching process may be performed by, for example, a dry etching process. The etching process may be performed using a gas having a high etch selectivity to the conductive layer 140, the gate spacer layer 120, and the device isolation layer 102. For example, in case the conductive layer 140 is formed using a polycrystalline silicon layer, the gate spacer layer 120 may be formed using a nitride layer and the device isolation layer 102 may be formed using an oxide layer, and CI gas and HBr gas having a high etch selectivity between the polycrystalline silicon layer, the nitride layer, and the oxide layer may be used as an etching gas. The high etch selectivity of these etching gases acts toward preventing the nitride layer or the oxide layer from being excessively etched during the process of removing the exposed portion of the polycrystalline silicon layer. Due to this etching process, the conductive layer 140 provided in a portion of the cell region 100 where a landing plug contact must not be formed, that is, the conductive layer 140 filling a second contact hole, is removed. In a similar manner, the etching process on the conductive layer 140 is also performed on the peripheral region 200. Therefore, the conductive layer 140 within the peripheral region 200 is also removed. After the etching process, the hard mask pattern is removed.

Referring to FIGS. 11 and 12, a buffer layer 170 is formed over the resulting structure. The buffer layer 170 substantially reduces and even prevents the phenomenon of impurities in a subsequently formed insulation layer penetrating downward. The buffer layer 170 may include, for example, a nitride layer having a thickness of approximately 30 Å to approximately 80 Å. An insulation layer 180 is formed over the buffer layer 170. The insulation layer 180 may include, for example, a boron phosphorous silicate glass (BPSG) oxide layer having a thickness of approximately 4,000 Å to approximately 6,000 Å. The BPSG oxide layer may be formed through a reflow process in a wet etching environment at a temperature of approximately 755° C. to approximately 800° C. During the deposition of the BPSG oxide layer, the penetration of impurities, for example, boron (B), can be substantially reduced by the buffer layer 170.

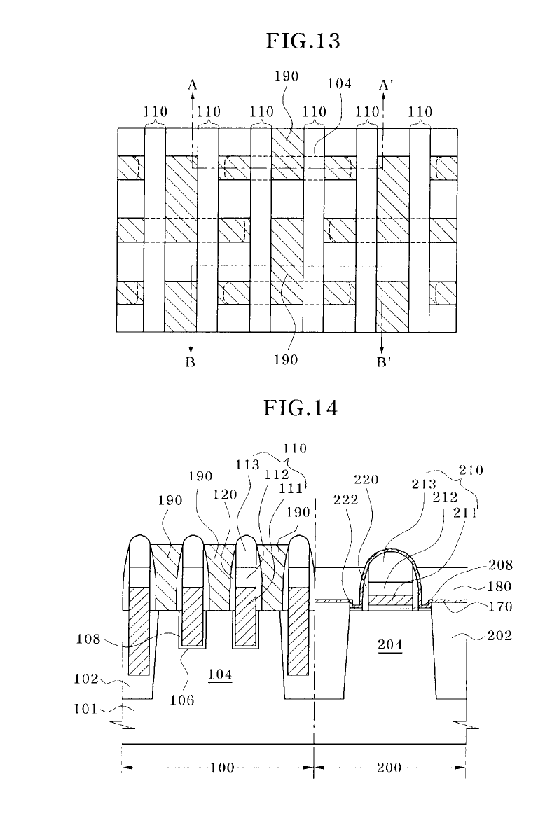

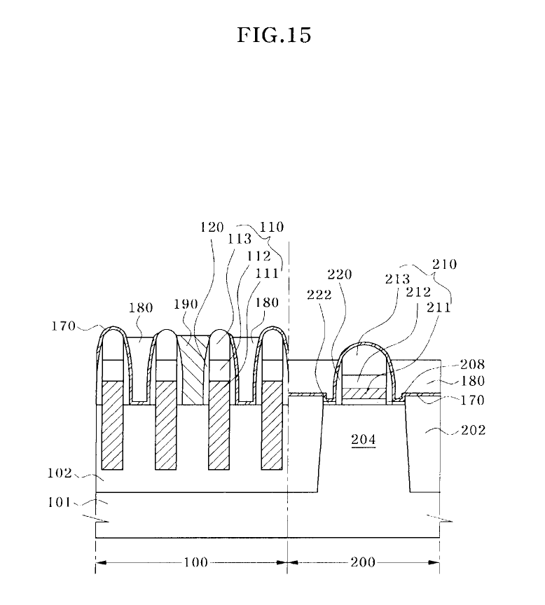

Referring to FIGS. 13 to 15, formation of landing plug contacts 190, which are mutually separated, is completed by a planarization process. The planarization process may be performed using a chemical mechanical polishing (CMP) process. As shown in FIGS. 13 and 14, the landing plug contacts 190 are formed to dispose over the active region 104 in the cell region 100 through performing the above-described processes. As illustrated in FIGS. 13 and 15, the insulation layer 180 is disposed over the device isolation region 120 in the cell region 100, and the landing plug contact 190 is disposed to extend in a predetermined region. Although not specifically shown in the accompanying drawings, an interlayer dielectric layer may be formed over the resulting structure. Subsequently, a bit line contact for coupling the bit line and the landing plug contact 190, and a storage node contact for coupling the storage node and the landing plug contact 190 are formed.

According to various embodiments of the present invention, after the gap between the gate spacer layers is filled with the conductive layer, the conductive layer disposed in regions except for a region where the landing plug contact will be formed is removed using the etching gas having a high etch selectivity between the conductive layer, the gate spacer layer, and the device isolation layer, thereby substantially reducing the landing plug not-open phenomenon and the bridge phenomenon which have occurred in forming the conventional landing plug contact. Moreover, the overall processes can be simplified because it is possible to omit the process of forming the landing plug contact hole in such a state that the insulation layer for formation of the existing landing plug contact is formed.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A method of fabricating a landing plug contact in a semiconductor memory device, the method comprising:
forming a device isolation layer defining an active region in a substrate;
forming a plurality of gate stacks over the substrate;
forming gate spacer layers at sides of each gate stack to define a first contact hole and a second contact hole, wherein the first contact hole is capable of being formed with a landing plug contact between the gate spacer layers, and wherein no landing plug contact is formed in the second contact hole;
forming a conductive layer to fill at least the first contact hole and the second contact hole;
forming a hard mask pattern over the conductive layer to expose the conductive layer filling the second contact hole;
removing the conductive layer filling the second contact hole by an etching process using the hard mask pattern as an etching barrier;
forming an insulation layer to fill at least the second contact hole in which the conductive layer is removed; and
forming a landing plug contact, which is insulated from an adjacent landing plug contact, within the contact hole by performing a planarization process on the insulation layer and the conductive layer.

2. The method of claim 1, wherein the hard mask pattern comprises an amorphous carbon layer.

3. The method of claim 1, wherein the etching process using the hard mask pattern as the etching barrier is performed using an etching gas having a high etch selectivity between the conducive layer, the gate spacer layer, and the device isolation layer.

4. The method of claim 3, wherein the conductive layer, the gate spacer layer, and the device isolation layer comprise a polycrystalline silicon layer, a nitride layer, and an oxide layer, respectively, and the etching gas comprises CI gas and HBr gas.

5. The method of claim 1, wherein the insulation layer comprises a boron phosphorous silicate glass (BPSG) oxide layer.

6. The method of claim 5, further comprising, before forming the BPSG oxide layer, forming a buffer layer which suppresses penetration of impurities.

7. The method of claim 6, wherein the buffer layer comprises a nitride layer.

8. A method of fabricating a landing plug contact in a semiconductor memory device, the method comprising:
forming a device isolation layer defining an active region in a substrate having a cell region and a peripheral region;
forming a plurality of gate stacks over the substrate;
forming gate spacer layers at sides of each gate stack to define a first contact hole and a second contact hole, wherein the first contact hole is capable of being formed with a landing plug contact between the gate spacer layers, and wherein no landing plug contact is formed in the second contact hole;
forming a conductive layer to fill at least the first contact and the second contact hole;
forming a hard mask pattern over the conductive layer to expose the conductive layer filling the second contact hole and the conducive layer within the peripheral region;
removing the conductive layer filling the second contact hole within the cell region and the conductive layer within the peripheral region by an etching process using the hard mask pattern as an etching barrier;
forming an insulation layer to fill at least the second contact hole in which the conductive layer is removed; and
forming a landing plug contact, which is insulated from an adjacent landing plug contact, within the contact hole by performing a planarization process on the insulation layer and the conductive layer.

9. The method of claim 8, wherein the hard mask pattern comprises an amorphous carbon layer.

10. The method of claim 8, wherein the etching process using the hard mask pattern as the etching barrier is performed using an etching gas having a high etch selectivity between the conducive layer, the gate spacer layer and the device isolation layer.

11. The method of claim 10, wherein the conductive layer, the gate spacer layer, and the device isolation layer comprise a polycrystalline silicon layer, a nitride layer, and an oxide layer, respectively, and the etching gas comprises CI gas and HBr gas.
